(19) United States
(12) Patent Application Publication
(10) Pub. No.: US 2005/0082628 A1
(43) Pub. Date: Apr. 21, 2005

(54) Semiconductor device and method of manufacturing the same

(76) Inventors: Hirohisa Kawasaki, Yokohama-shi (JP); Kazuaki Isobe, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/739,087

(22) Filed: Dec. 19, 2003

(30) Foreign Application Priority Data
Oct. 21, 2003 (JP) 2003-360727

(51) Int. Cl. H01L 29/76

(52) U.S. Cl. 257/435

(57) ABSTRACT

A semiconductor device which is here disclosed includes a first wiring layer having a first lower end and a first upper end protruded more than the first lower end, and a second wiring layer having a second lower end and a second upper end protruded more than the second lower end, the second upper end facing the first upper end with the interposition of a first gap, and the second lower end facing the first lower end with the interposition of a second gap larger than the first gap.

### CROSS-REFERENCE TO RELATED APPLICATIONS

This application is based upon and claims the benefit of priority from the prior Japanese Patent Application No. 2003-360727, filed Oct. 21, 2003, the entire contents of which are incorporated herein by reference.

### BACKGROUND OF THE INVENTION

1. Field of the Invention

The present invention relates to a semiconductor device which comprises a highly integrated circuit to realize a micromemory cell, and a method of manufacturing the same.

2. Description of the Related Art

A biggest problem for cell size reduction in a static random access memory (SRAM) of a point-symmetric type has conventionally been a difficulty of reducing a space of an abutting portion between gate electrodes and an overlapping length between the gate electrode and an active region for a layout. The abutting portion between the gate electrodes indicates a region in the vicinity between ends of the two gate electrodes in an extended direction (direction perpendicular to a direction of a gate length).

As shown in FIG. 38, there are two kinds of abutting portions between gate electrodes in the SRAM of the point-symmetric type. One is an abutting portion A between gate electrodes of a driver and a transistor which face each other in adjacent cells, and the other is an abutting portion B between gate electrodes of a cross couple portion of a load transistor and a transfer transistor.

In one memory cell 50 of the SRAM of the point-symmetric type, there are abutting portions A between gate electrodes, one each at right and left ends of the cell 50, and there are two abutting portions B in the cell, which make three abutting portions A and B in total.

However, in the conventional art, an impossibility of making spaces of the abutting portions A, B shorter than a certain length when the abutting portions A, B between the gate electrodes are formed has been a problem for cell size reduction.

In transfer by a conventional method, there are photolithographic resolution limits of a mask and a resist, and a limit of a narrow space to be processed by reactive ion etching (RIE). Consequently, minimum lengths of the abutting portions A, B are determined by such limit values.

In a currently used microprocess of a design rule 0.4 μm or lower, optical proximity effects are conspicuous during lithography. Thus, gates and active regions must be overlapped more than a certain length for a layout in view of influences of shortening and rounding of a resist end and lithographic misalignment. In other words, since the spaces and the overlapped lengths of the abutting portions A, B cannot be made shorter, the isolation region cannot be narrowed. As a result, it is very difficult to reduce a cell size.

Furthermore, in transfer which uses Levenson mask as one of superresolution technologies considered to be advantageous for forming a narrow space portion, in the case of the SRAM of the point-symmetric type, the space of the abutting portion between the gate electrodes is realized by applying double patterning. After forming the straight gate electrode, trimming these gate electrodes are carried out. However, a space size of the abutting portion is determined by a limit of lithography during the trimming (see “M. Kanda et al., VLSI Symp., 2003 submitted Highly Stable 65 nm Node (CMOS 5) 0.56 μm2 SRAM Cell Design for Very Low Operation Voltage”). The Levenson mask has problems of TAT and costs because work such as shifter sticking is very difficult.

### BRIEF SUMMARY OF THE INVENTION

A semiconductor device according to a first aspect of the present invention comprises a first wiring layer having a first lower end and a first upper end protruded more than the first lower end; and a second wiring layer having a second lower end and a second upper end protruded more than the second lower end, the second upper end facing the first upper end with the interposition of a first gap, and the second lower end facing the first lower end with the interposition of a second gap larger than the first gap.

A method for manufacturing a semiconductor device according to a second aspect of the present invention comprises forming a first insulating film; selectively removing the first insulating film by anisotropic etching to form a first dummy block formed of the first insulating film in a predetermined region; slimming the first dummy block by isotropic etching; forming a conductive film to cover the first dummy block; removing the conductive film until an upper surface of the first dummy block is exposed; and patterning the conductive film to form first and second wiring layers formed of the conductive films divided by the first dummy block.

### BRIEF DESCRIPTION OF THE SEVERAL VIEWS OF THE DRAWING

FIG. 1 is a plan view showing a semiconductor device according to a first embodiment of the present invention;

FIG. 2 is a sectional view of the semiconductor device cut along the line II-II of FIG. 1;

FIG. 3 is a plan view showing a manufacturing process of the semiconductor device of the first embodiment of the present invention;

FIG. 4 is a sectional view of the semiconductor device cut along the line IV-IV of FIG. 3;

FIG. 5 is a plan view showing a manufacturing process of the semiconductor device of the first embodiment of the present invention sequent to that of FIG. 3;

FIG. 6 is a sectional view of the semiconductor device cut along the line VI-VI of FIG. 5;

FIG. 7 is a plan view showing a manufacturing process of the semiconductor device of the first embodiment of the present invention sequent to that of FIG. 5;

FIG. 8 is a sectional view of the semiconductor device cut along the line VIII-VIII of FIG. 7;

FIG. 9 is a plan view showing a manufacturing process of the semiconductor device of the first embodiment of the present invention sequent to that of FIG. 7;

FIG. 10 is a sectional view of the semiconductor device cut along the line X-X of FIG. 9;

FIG. 11 is a plan view showing a manufacturing process of the semiconductor device of the first embodiment of the present invention sequent to that of FIG. 9;

FIG. 12 is a sectional view of the semiconductor device cut along the line XII-XII of FIG. 11;

FIG. 13 is a plan view showing a manufacturing process of the semiconductor device of the first embodiment of the present invention sequent to that of FIG. 11;

FIG. 14 is a sectional view of the semiconductor device cut along the line XIV-XIV of FIG. 13;

FIG. 15 is a plan view showing the semiconductor device of the first embodiment of the present invention;

FIG. 16 is a plan view showing a semiconductor device according to a second embodiment of the present invention;

FIG. 17 is a sectional view of the semiconductor device cut along the line XVII-XVII of FIG. 16;

FIG. 18 is a plan view showing a manufacturing process of the semiconductor device of the second embodiment of the present invention;

FIG. 19 is a sectional view of the semiconductor device cut along the line XIX-XIX of FIG. 18;

FIG. 20 is a plan view showing a manufacturing process of the semiconductor device of the second embodiment of the present invention sequent to that of FIG. 18;

FIG. 21 is a sectional view of the semiconductor device cut along the line XXI-XXI of FIG. 20;

FIG. 22 is a plan view showing a manufacturing process of the semiconductor device of the second embodiment of the present invention sequent to that of FIG. 20;

FIG. 23 is a sectional view of the semiconductor device cut along the line XXIII-XXIII of FIG. 22;

FIG. 24 is a plan view of a semiconductor device according to a conventional art;

FIG. 25 is a plan view showing the semiconductor device of the second embodiment of the present invention;

FIG. 26 is a plan view showing a manufacturing process of a semiconductor device according to a third embodiment of the present invention;

FIG. 27 is a sectional view of the semiconductor device cut along the line XXVII-XXVII of FIG. 26;

FIG. 28 is a plan view showing a manufacturing process of the semiconductor device of the third embodiment of the present invention sequent to that of FIG. 26;

FIG. 29 is a sectional view of the semiconductor device cut along the line XXIX-XXIX of FIG. 28;

FIG. 30 is a plan view showing a manufacturing process of the semiconductor device of the third embodiment of the present invention sequent to that of FIG. 28;

FIG. 31 is a sectional view of the semiconductor device cut along the line XXXI-XXXI of FIG. 30;

FIG. 32 is a plan view showing a manufacturing process of the semiconductor device of the third embodiment of the present invention;

FIG. 33 is a sectional view of the semiconductor device cut along the line XXXIII-XXXIII of FIG. 32;

FIG. 34 is a plan view showing a manufacturing process of the semiconductor device of the third embodiment sequent to that of FIG. 32;

FIG. 35 is a sectional view of the semiconductor device cut along the line XXXV-XXXV of FIG. 34;

FIG. 36 is a plan view showing a manufacturing process of the semiconductor device of the third embodiment of the present invention sequent to that of FIG. 34;

FIG. 37 is a sectional view of the semiconductor device cut along the line XXXVI-XXXVI of FIG. 36; and

FIG. 38 is a plan view of a semiconductor device according to a conventional art.

### DETAILED DESCRIPTION OF THE INVENTION

According to the preferred embodiments of the present invention, for the purpose of further reducing a memory size of a highly integrated logic circuit, a static random access memory (SRAM) or the like, a dummy block is arranged in a place in which a narrow space is formed, and a line pattern is divided by the dummy block. Each embodiment of the invention will be described by way of example in which such a structure is applied to an SRAM of a point-symmetric type. However, the embodiment is not limited to this example, and the structure can be applied to various places to reduce a space between patterns.

Hereinafter, the embodiments of the present invention will be described with reference to the accompanying drawings. In the description, common portions are denoted by common reference numerals in all the drawings.

[First Embodiment]

A first embodiment is an example in which a space of an abutting portion between gate electrodes of driver transistors in adjacent cells of an SRAM of a point-symmetric type is reduced.

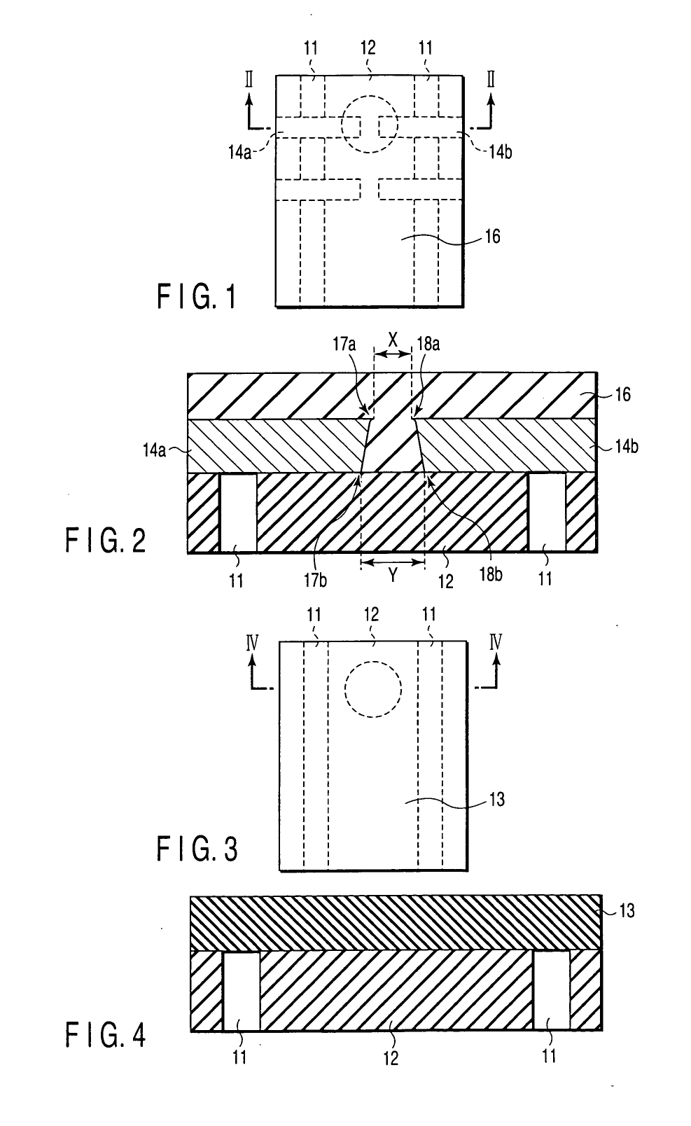

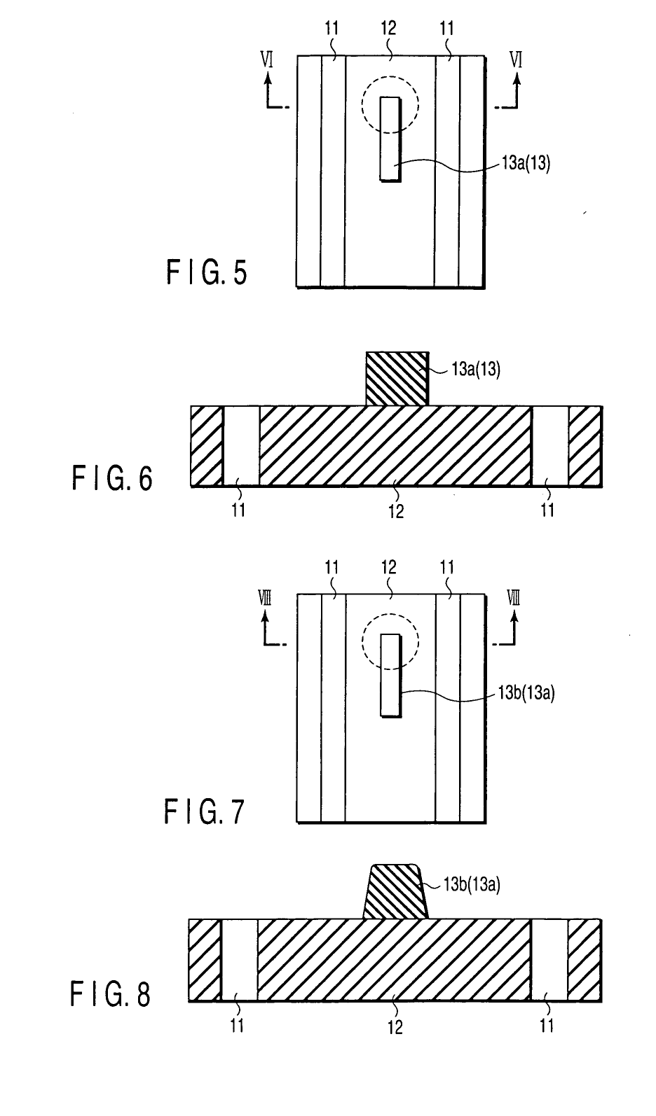

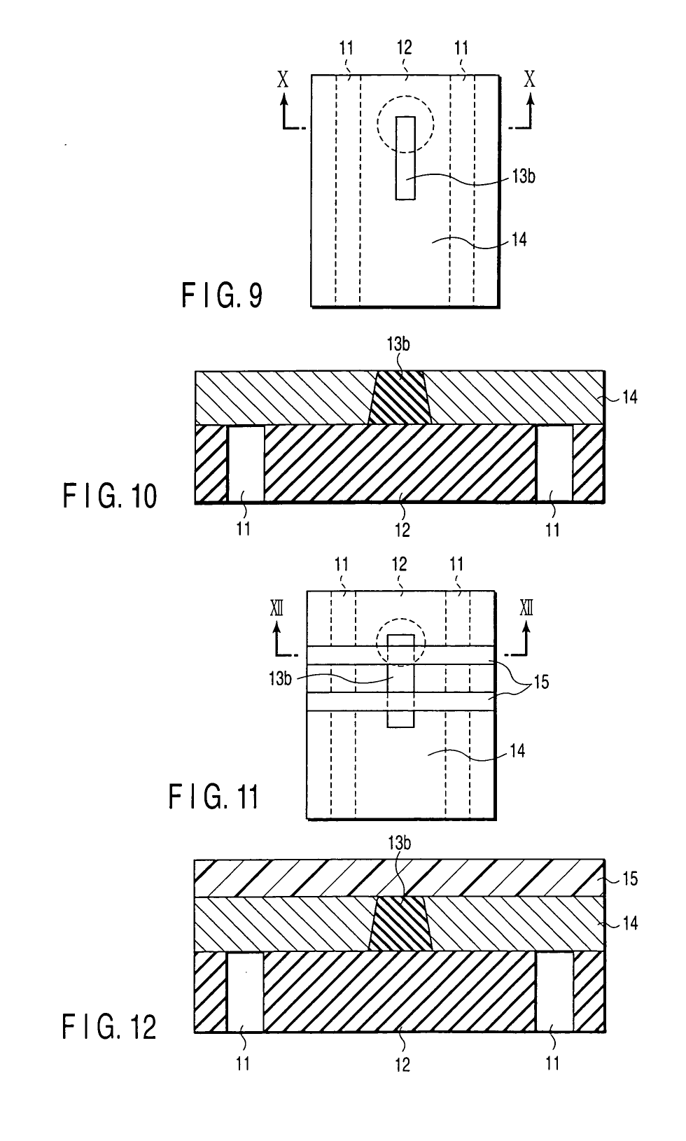

FIGS. 1 and 2 are plan and sectional views of a semiconductor device according to the first embodiment of the present invention. As shown in FIGS. 1 and 2, a first gate electrode 14a has a lower end 17b and an upper end 17a protruded more than the lower end 17b in an end of an extended direction (direction perpendicular to a direction of a gate length). Similarly, a second gate electrode 14b has a lower end 18b and an upper end 18a protruded more than the lower end 18b in an end of an extended direction (direction perpendicular to a direction of a gate length).

The upper end 17a of the first electrode 14a and the upper end 18a of the second electrode 14b face each other with the interposition of a first gap X, and the lower end 17b of the first gate electrode 14a and the lower end 18b of the second gate electrode 14b face each other with the interposition of a second gap Y. The second gap Y is larger than the first gap X.

Slopes are formed from the lower ends 17b, 18b to the upper ends 17a, 18a so that the ends of the gate electrodes 14a, 14b in the extended directions can gradually approach each other toward the upper surfaces.

In the case of a conventional art, if a space is formed between the gate electrodes 14a, 14b, the upper ends 17a, 18a of the gate electrodes 14a, 14b have gentle curves due to shortening and rounding of a resist during exposure. In the case of the first embodiment, however, a space between the gate electrodes 14a, 14b is formed not by a transcription of the space between resists but by a dummy block as described later. Thus, since this space has a dummy block shape, the upper ends 17a, 18a of the gate electrodes 14a, 14b have squarish shapes which reflect shapes of slimmed dummy blocks.

FIGS. 3 and 14 are plan and sectional views of a manufacturing process of the semiconductor device of the first embodiment of the present invention. Hereinafter, a manufacturing method of the semiconductor device of the first embodiment will be described.

As shown in FIGS. 3 and 4, as in the case of conventional formation of an integrated MOS transistor, an active region 11 and an isolation region 12 constituted of an insulting film are formed in a semiconductor substrate. Then, a dummy block insulating film 13 is deposited to form a dummy block. This dummy block insulating film 13 should enable setting of a selection ratio of etching with a gate electrode material (e.g., polysilicon film) and an insulating film which is filled with (e.g., plasma enhanced CVD SiO₂ film, or a tetra ethyl ortho silicate (TEOS) film) of the isolation region 12. For example, a boron silicate glass (BSG) film or a boron phosphorous silicate glass (PBSG) film is used.

Then, as shown in FIGS. 5 and 6, the dummy block insulating film 13 is patterned by lithography and anisotropic etching, e.g., reactive ion etching (RIE), to form a dummy block 13a which end is vertically cut. This dummy block 13a is formed only in an abutting portion between gate electrodes which is a place to become a narrow space.

Then, as shown in FIGS. 7 and 8, the dummy block 13a is slimmed by isotropic etching, e.g., chemical dry etching (CDE) or wet etching. As a result, a dummy block 13b having a thin size which exceeds a resolution limit of lithography is formed. The dummy block 13b becomes trapezoidal in shape in which an upper surface is smaller than a bottom surface.

Then, a gate dielectric (not shown) is formed, which may be carried out before the dummy block insulating film 13 is deposited.

Then, as shown in FIGS. 9 and 10, a gate electrode material 14 constituted of, e.g., a polysilicon film, is deposited to cover the dummy block 13b. Then, the gate electrode material 14 is removed by full-surface etching-back until the upper surface of the dummy block 13b is exposed.

Then, as shown in FIGS. 11 and 12, a resist 15 patterned by lithography is formed. This resist 15 is a line structure across over the dummy block 13b.

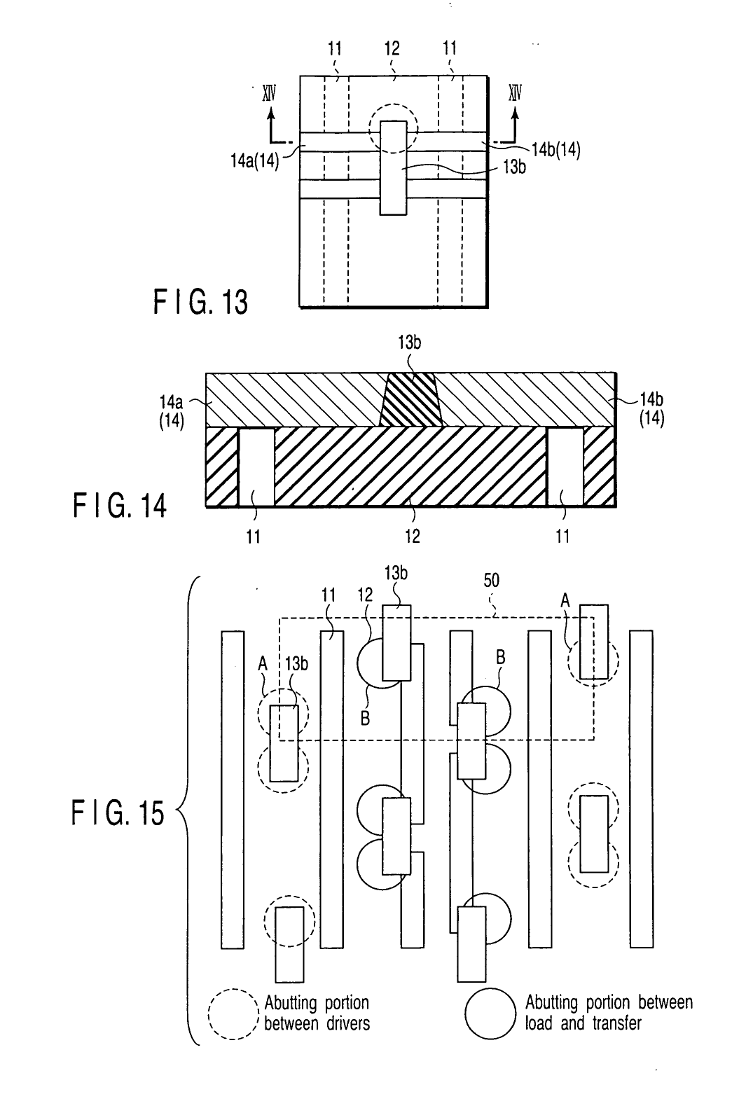

Then, as shown in FIGS. 13 and 14, the gate electrode material 14 is patterned by RIE while the patterned resist 15 is used as a mask. Accordingly, gate electrodes 14a, 14b separated by the dummy block 13b are formed.

Then, as shown in FIGS. 1 and 2, after removal of the dummy block 13b, an interlayer insulating film 16 is formed to fill in a space between the gate electrodes 14a, 14b.

According to the first embodiment, the dummy block 13a is first arranged in the place in which the narrow space is formed, this dummy block 13a is slimmed to form the dummy block 13b, and then the gate electrode material 14 is deposited to be patterned. Thus, the gate electrode material 14 can be divided by the dummy block 13b. In this case, since a size of the dummy block 13b defines a space width between the gate electrodes 14a, 14b, the gate electrodes 14a, 14b separated in a narrow space which exceeds the resolution limit of lithography can be formed by slimming the dummy block 13a. Further, as it is not necessary to take influences of shortening and rounding of the resist into consideration, an overlapped length between the gate electrode and the active region can be reduced. As a result, in an LSI in which transistor integration is limited by a space distance of an abutting portion between gate electrodes and an overlapped length, it is possible to form a circuit of higher integration by using the first embodiment.

Especially, in the SRAM of the point-symmetric type, as shown in FIG. 15, since there are three isolation regions which include abutting portions A, B between the gate electrodes in space in one cell 50, if the dummy block 13b are arranged herein, isolation distance can be reduced. This has a large influence on a reduction of a memory cell size. Specifically, while a distance between the adjacent electrodes has conventionally been 80 nm in a 45 nm generation, according to the first embodiment, a distance X between the upper ends 17a, 18a of the adjacent gate electrodes 14a, 14b can be reduced to 15 to 20 nm.

Additionally, by using the dummy block 13b, as shown in FIG. 11, the resist 15 can be patterned as a continuous line without considering a space between the gate electrodes. Thus, since optical proximity effects (OPE) or process proximity effects (PPE) need not be taken into consideration for transfer of the narrow space portion, not only a mask development process (MDP) can become simple but also mask formation by electron beam (EB) can become very easy. Moreover, during transfer of a pattern onto a wafer, an exposure margin can be increased because there is no need to expose a very small space of an abutting portion between the gate electrodes.

[Second Embodiment]

A second embodiment is an example in which a space of an abutting portion between gate electrodes of a load transistor and a transfer transistor in an SRAM of a point-symmetric type is reduced.

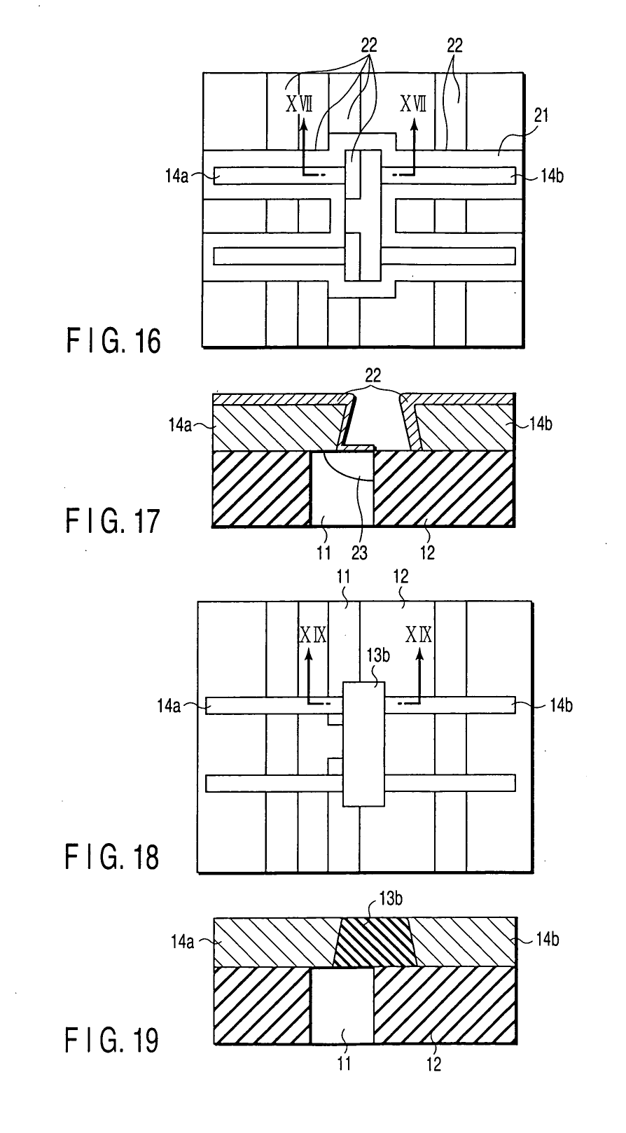

FIGS. 16 and 17 are plan and sectional views of a semiconductor device according to the second embodiment of the present invention. As shown in FIGS. 16 and 17, in a structure similar to that of the first embodiment, a gate electrode material is divided by a dummy block to place first and second gate electrodes 14a and 14b by setting a narrow space. Then, a silicide film 22 is formed on upper surfaces of the first and second gate electrodes 14a, 14b, opposite side faces of the first and second gate electrodes 14a, 14b, and an upper surface of an active region 11. Accordingly, the first gate electrode 14a and the active region 11 are electrically connected to each other by the silicide film 22 without using any contact holes.

A side wall insulating film 21 is formed on side faces of a dummy block and the gate electrodes 14a, 14b. Thus, the side wall insulating film 21 is continuously formed not only on the side walls of the gate electrodes but across over side faces of adjacent gate electrodes. For example, in the case of FIG. 16, since the side wall insulating film 21 is formed along side faces of four gate electrodes to be continuous over the adjacent gate electrodes, it makes a round to surround the four gate electrodes.

FIGS. 18 to 25 are plan and sectional views showing a manufacturing process of the semiconductor device of the second embodiment of the present invention. Hereinafter, a manufacturing method of the semiconductor device of the second embodiment will be described.

First, as shown in FIGS. 18 and 19, by a technique similar to that of the first embodiment, gate electrodes 14a, 14b divided by a dummy block 13b are formed. Subsequently, without removing the dummy block 13b, ions of As or B are implanted to form an extension region (not shown) in an active region 11.

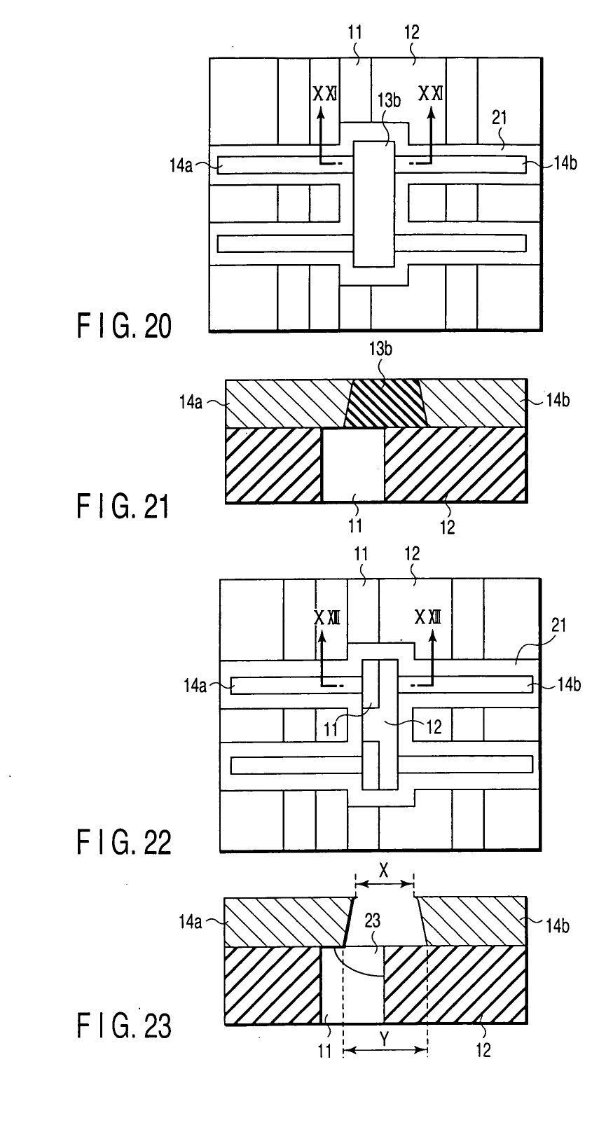

Then, as shown in FIGS. 20 and 21, a side wall insulating film (e.g., silicon nitride film) 21 is formed on side faces of the gate electrodes 14a, 14b and the dummy block 13b. According to the second embodiment, an insulating film constituting the dummy block 13b must enable setting of a selection ratio of etching not only with a gate electrode film and an insulating film of an isolation region 12 but also with a film of an outermost periphery constituting the side wall insulating film 21.

Then, as shown in FIGS. 22 and 23, only the dummy block 13b is selectively removed by etching of hydrogen fluoride (HF) steam or the like. Accordingly, an upper surface of the active region 11 between the gate electrodes 14a, 14b and side faces of ends of the gate electrodes 14a, 14b are exposed. Subsequently, ions of As or B are implanted to form a source/drain diffusion region 23 in the active region 11.

Then, as shown in FIGS. 16 and 17, by a salicide (self-aligned silicide) process, silicon of a semiconductor substrate is reacted with a high-melting point metal (e.g., W, Mo, Ta, Ti, Co, Ni, Pt or the like) to form a silicide film 22 on the upper surfaces of the gate electrodes 14a, 14b, the side faces of the gate electrodes 14a, 14b and the active region 11 between the gate electrodes 14a, 14b. As a result, the gate electrode 14a is electrically connected to the active region (semiconductor substrate) 11 by the silicide film 22.

According to the second embodiments, not only effects similar to those of the first embodiment but also the following effects can be obtained.

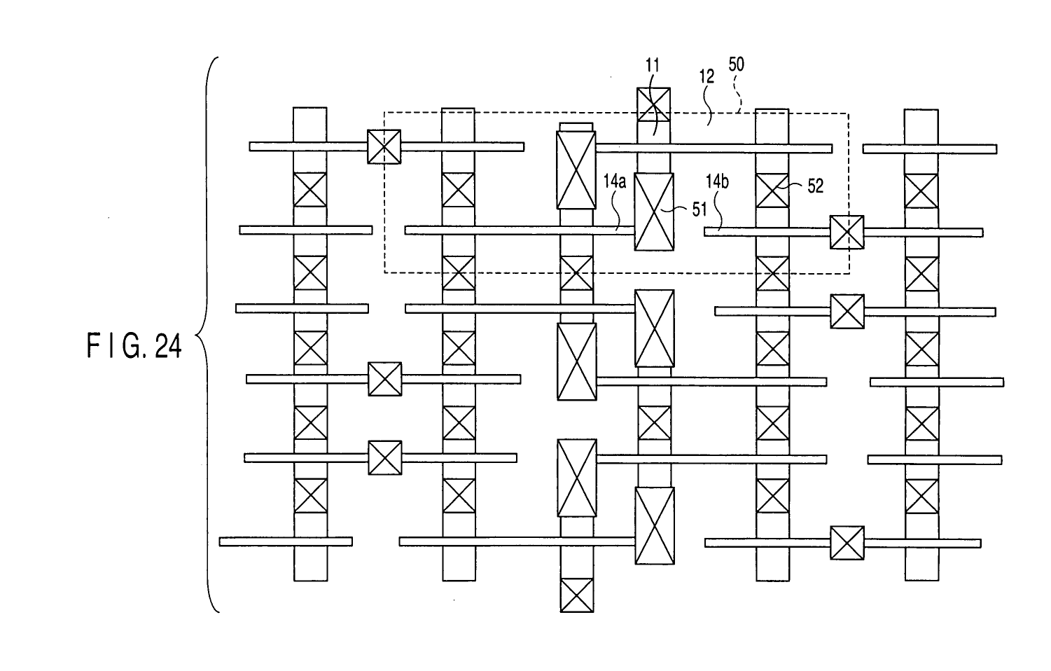

Conventionally, in the SRAM of the point-symmetric type, as shown in FIG. 24, a technology of a large shared contact (SC) 51 over the gate electrode 14a and the silicon substrate has been employed in order to electrically connect the gate electrode 14a to the silicon substrate (active region 11) (see Jpn. Pat. Appln. KOKAI Publication No. 11-150268). A hole of this shared contact 51 is formed simultaneously with the other contact hole 52 on the silicon substrate or the gate electrode. However, a reduction in a cell size has been accompanied by an impossibility of obtaining a sufficient exposure margin to simultaneously form the large shared contact 51 (e.g., SC size of the point-symmetrical SRAM of the 45 nm generation is approximately 150 nm×70 nm) over the gate electrode 14a and the silicon substrate, and the other small contact 52 (e.g., contact hole size of the point-symmetrical SRAM of the 45 nm generation is approximately 70 nm×70 nm) . Thus, a need has arisen to separately exposure the shared contact 51 and the other contact 52.

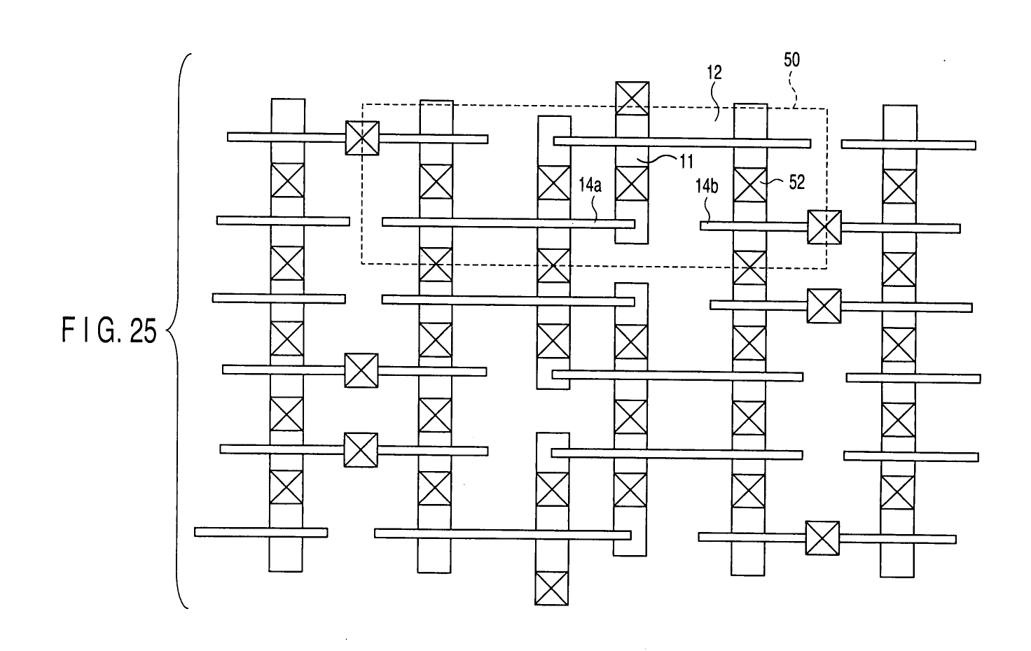

On the other hand, according to the second embodiment, the side wall insulating film 21 is not removed by using etching such as lithography or RIE, and only the dummy block 13b is selectively removed to enable direct exposure of an end of the gate electrode 14a on the active region 11 as shown in FIG. 25. Thus, there is an effect that the gate electrode 14a and the active region 11 can be electrically connected to each other by employing the salicide process. Therefore, since the gate electrode 14a and the active region 11 can be electrically connected to each other by the silicide film 22, no shared contact is necessary over the gate electrode 14a and the active region 11. As a result, the shared contact 51 over the gate electrode and the silicon substrate which has been one of the problems for reduction of the cell size of the SRAM of the point-symmetric type is made unnecessary, and not only an exposure margin during lithography of the contact hole can be improved, but also a cost increase can be suppressed since separate exposure of the contacts 51, 52 is unnecessary.

[Third Embodiment]

A third embodiment is an example in which a dummy block is applied to a structure of using a side wall image transfer technology.

As described above with reference to the first and second embodiments, if the method of separating the gate electrodes by the dummy block is used, it is not necessary to separate the gate electrodes present by sandwiching the narrow space on the mask, and they can be drawn as one line on the mask. On the other hand, for example, in the case of forming gate electrodes by using the side wall image transfer technology, a side wall portion formed on an outer periphery of a dummy block (note: this dummy block is for the use of the side wall image transfer technology, and different from that of each of the embodiments of the invention) is transferred to the gate electrodes. Thus, the gate electrodes can be patterned as one line of a “□” shape in which there are no breaks.

If the dummy block technology of the first and second embodiments is combined with the side wall image transfer technology, for example, the following is realized.

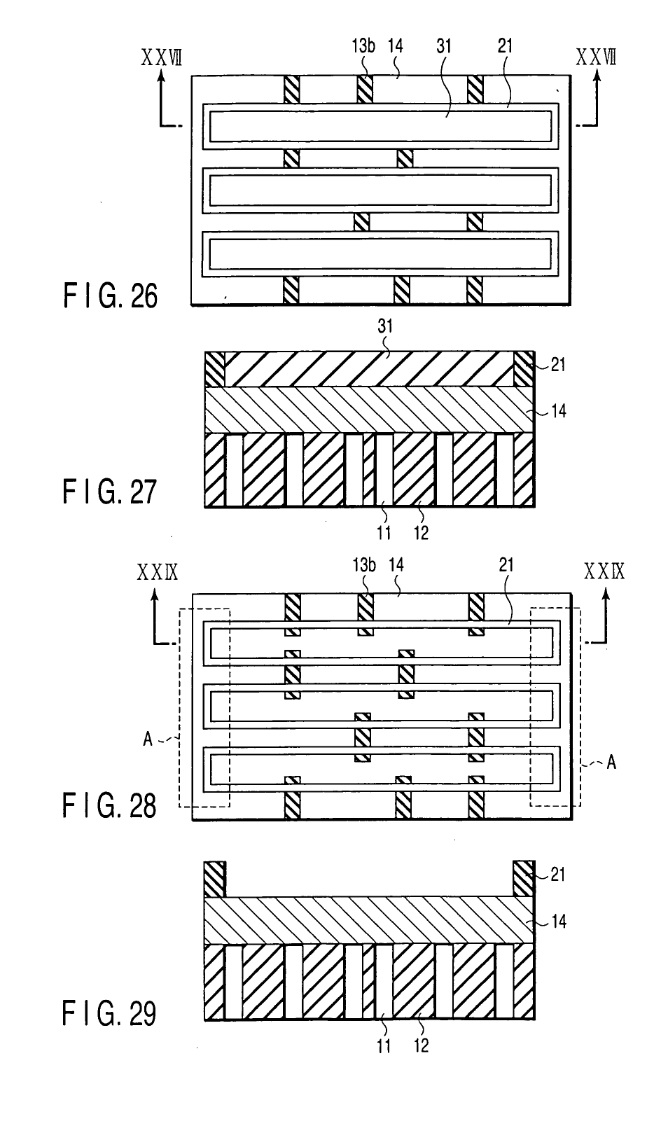

First, as shown in FIGS. 26 and 27, a dummy block 13b is formed in a predetermined region by a technique similar to that of each of the embodiments. Then, a gate electrode material (e.g., polysilicon film) 14 is formed to cover the dummy block 13b, and this gate electrode material 14 is flattened and removed until an upper surface of the dummy block 13b is exposed. Then, a side wall formation insulating film (e.g., silicon oxide film) 31 is deposited on the dummy block 13b and the gate electrode material 14, and patterned by lithography. Then, a side wall insulating film (e.g., silicon nitride film) 21 is deposited, and the side wall insulating film 21 is left on a side face of the insulating film 31 by RIE.

Then, as shown in FIGS. 28 and 29, the insulating film 31 is removed by isotropic etching of NH₄F or the like. A chemical solution used for the isotropic etching should enable setting of a selection ratio between the insulating film 31, and the side wall insulating film 21 on its side face, the gate electrode material 14, preferably setting of a selection ratio between the insulating film 31 and the dummy block 13b.

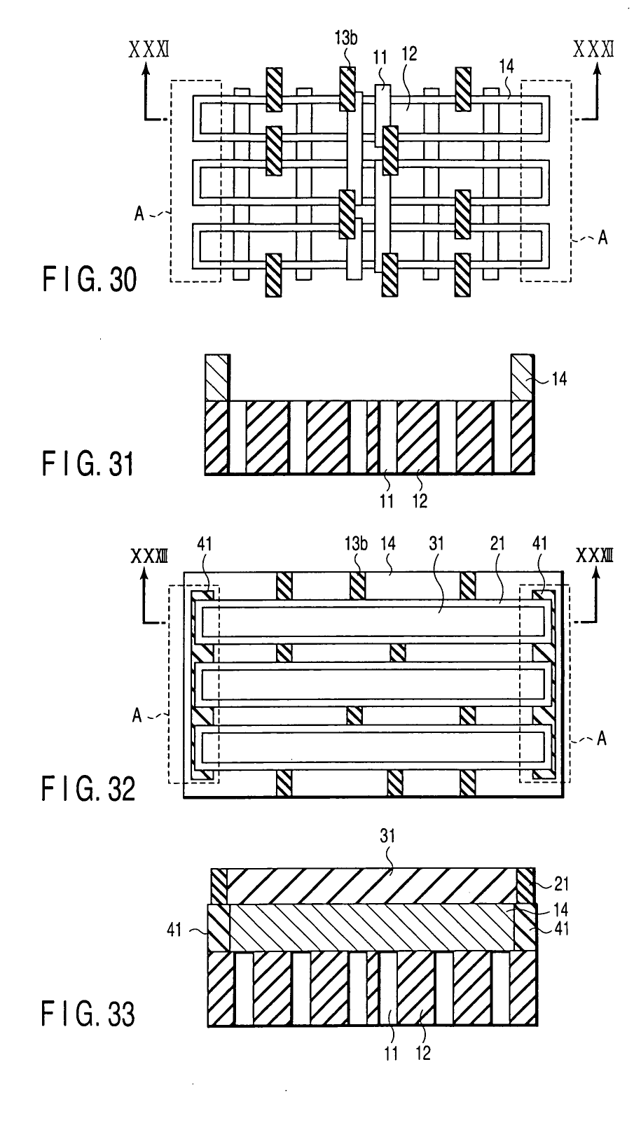

Then, as shown in FIGS. 30 and 31, a pattern is transferred to the gate electrode material 14 by using the left side wall insulating film 21 as a mask. Accordingly, a structure similar to that of each of the first and second embodiments is formed in which the gate electrode material 14 is separated by the dummy block 13b.

However, in the process shown in FIGS. 26 to 31, the side wall insulating film 21 is formed on all sides of the outer periphery of the side wall formation insulating film 31. Consequently, as shown in FIG. 30, the separate portions of the gate electrode material 14 are connected in a region A. Thus, since it is necessary to remove the unnecessary side wall insulating film 21 of the region A shown in FIG. 28, lithography and RIE steps must be added to remove the side wall insulating film 21 of the region A.

In such a case, it is advised to add a dummy block to the region A. Specifically, the following manufacturing method is employed.

First, as shown in FIGS. 32 and 33, by a technique similar to that of each of the embodiments, a dummy block 13b is formed, and a dummy block 41 is also formed in the region A in which gate electrode should not be formed. Then, a gate electrode material (e.g., polysilicon film) 14 is formed to cover the dummy blocks 13b, 41, and this gate electrode material 14 is flattened and removed until upper surfaces of the dummy blocks 13b, 41 are exposed. Then, a side wall formation insulating film (e.g., silicon oxide film) 31 is deposited on the dummy blocks 13b, 41 and the gate electrode material 14, and a pattern is transferred to this insulating film 31 by lithography. Then, after a side wall insulating film (e.g., silicon nitride film) 21 is deposited, the side wall insulating film 21 is left only on a side face of the insulating film 31 by RIE.

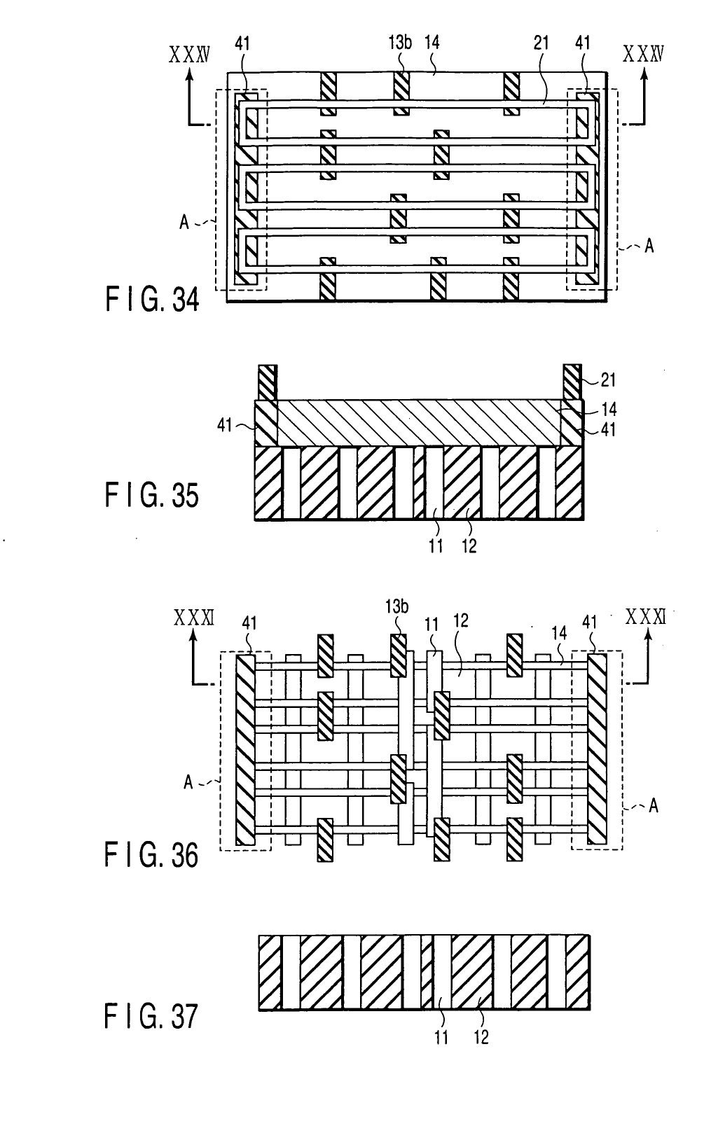

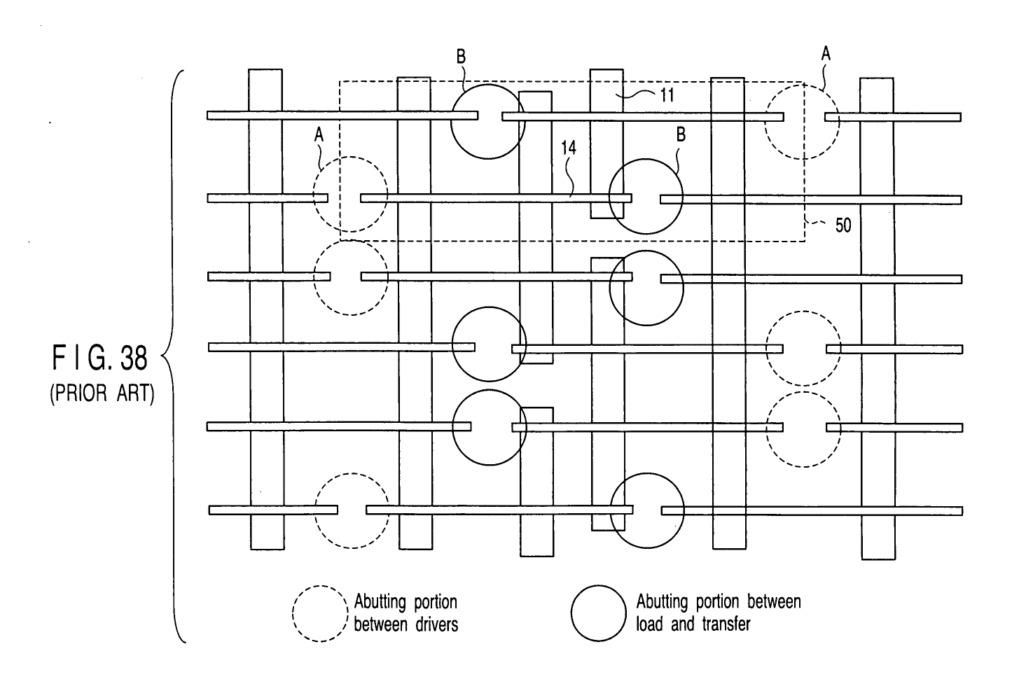

Then, as shown in FIGS. 34 and 35, the insulating film 31 is removed by isotropic etching of NH₄F or the like.

Then, as shown in FIGS. 36 and 37, a pattern is transferred to the gate electrode material 14 by using the left side wall insulating film 21 as a mask. Accordingly, a structure is realized in which not only the gate electrode material 14 is separated by the dummy block 13b but also the gate electrode material 14 of the region A (end around the side wall insulating film 21) is separated by the dummy block 41.

According to the third embodiment, not only effects similar to those of the first embodiment but also the following effects can be obtained.

Even in the case of using the side wall image transfer technology, the dummy block 41 is formed below (region A) the side wall insulating film 21 in which gate electrode should not be formed to prevent formation of a gate electrode in this portion. Thus, since a desired pattern is formed without removing the side wall insulating film 21 of the unnecessary portion by using etching such as lithography or RIE, the number of steps can be reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

1. A semiconductor device comprising:
a first wiring layer having a first lower end and
a first upper end protruded more than the first lower end; and
a second wiring layer having a second lower end and a second upper end protruded more than the second lower end, the second upper end facing the first upper end with the interposition of a first gap, and the second lower end facing the first lower end with the interposition of a second gap larger than the first gap.

2. The semiconductor device according to claim 1, wherein the first and second upper ends have squarish shapes.

3. The semiconductor device according to claim 1, wherein the first and second wiring layers are gate electrodes.

4. The semiconductor device according to claim 1, wherein the first and second wiring layers are gate electrodes of driver transistors facing each other in adjacent cells of an SRAM of a point-symmetrical type.

5. The semiconductor device according to claim 1, further comprising:
a semiconductor substrate which is formed below the first and second wiring layers across the first and second wiring layers; and
a silicide film which is formed on an upper surface of the semiconductor substrate between the first and second wiring layers, an upper surface of the first wiring layer, and a side face of the first wring layer opposite to the second wiring layer to electrically connect the first wiring layer to the semiconductor substrate.

6. The semiconductor device according to claim 5, further comprising a side wall insulating film which is continuously formed along side faces of the first and second wiring layers across the first and second wiring layers.

7. The semiconductor device according to claim 5, wherein the first and second wiring layers are a gate electrode of a load transistor and a gate electrode of a transfer transistor in an SRAM of a point-symmetrical type.

8. A method for manufacturing a semiconductor device, comprising:
forming a first insulating film;
selectively removing the first insulating film by anisotropic etching to form a first dummy block formed of the first insulating film in a predetermined region;
slimming the first dummy block by isotropic etching;
forming a conductive film to cover the first dummy block;
removing the conductive film until an upper surface of the first dummy block is exposed; and
patterning the conductive film to form first and second wiring layers formed of the conductive films divided by the first dummy block.

9. The method according to claim 8,
wherein the first wiring layer has a first lower end and a first upper end protruded more than the first lower end,
the second wiring layer has a second lower end and a second upper end protruded more than the second lower end,
the second upper end faces the first upper end with the interposition of a first gap, and the second lower end faces the first lower end with the interposition of a second gap larger than the first gap.

10. The method according to claim 9, wherein the first and second upper ends have squarish shapes.

11. The method according to claim 8, wherein the first and second wiring layers are gate electrodes.

12. The method according to claim 8, wherein the first and second wiring layers are gate electrodes of driver transistors facing each other in adjacent cells of an SRAM of a point-symmetrical type.

13. The method according to claim 8, further comprising:
forming a side wall insulating film on side faces of the first dummy block and the first and second wiring layers;
removing the first dummy block to expose an upper surface of an active region between the first and second wiring layers; and
forming a silicide film on the upper surface of the active region, upper surfaces of the first and second wiring layers, and opposite side faces of the first and second wiring layers.

14. The method according to claim 13, wherein the first wiring layer is electrically connected to the active region by the silicide film.

15. The method according to claim 13, wherein the first dummy block is removed with HF steam.

16. The method according to claim 13, the first and second wiring layers are a gate electrode of a load transistor and a gate electrode of a transfer transistor in an SRAM of a point-symmetrical type.

17. The method according to claim 8, further comprising, before the patterning of the conductive film:
forming a second insulating film on the conductive film;
patterning the second insulating film;
forming a side wall insulating film on a side face of the patterned second insulating film; and
removing the second insulating film,
wherein the conductive film is patterned by using the side wall insulating film as a mask.

18. The method according to claim 17,
wherein when the first dummy block is formed, a second dummy block formed of the first insulating film is formed below an end of the side wall insulating film, and the conductive film is divided by the second dummy block.

19. The method according to claim 17,
wherein the second insulating film is removed by isotropic etching.
